(19) United States
(12) Patent Application Publication
(10) Pub. No.: US 2025/0324552 A1
(43) Pub. Date: Oct. 16, 2025

(54) THERMAL BRIDGE FOR AN ELECTRICAL COMPONENT

(71) Applicant: TE Connectivity Solutions GmbH, Schaffhausen (CH)

(72) Inventor: Alan Weir Bucher, Manheim, PA (US)

(21) Appl. No.: 18/636,413

(22) Filed: Apr. 16, 2024

(51) Int. Cl. H05K 7/20

(52) U.S. Cl. CPC H05K 7/20454; H05K 7/2049

(57) ABSTRACT

A thermal bridge includes an upper bridge assembly including upper plates and a lower bridge assembly including lower plates. The upper and lower plates are segmented including forward segments and rearward segments meeting at a seam. The ends of the lower plates face and thermally couple to an electrical component. The sides of some of the lower plates face the sides of some of the upper plates to thermally interface the lower plates with the upper plates. The thermal bridge includes a spring element positioned between the upper bridge assembly and the lower bridge assembly. The thermal bridge includes a bridge frame supporting the upper plates and the lower plates. The bridge frame includes open limit spars engaging the plates at the seam to limit spreading apart of the plates from each other against the opening forces of the spring element.

### BACKGROUND OF THE INVENTION

The subject matter herein relates generally to heat dissipation for electrical components.

It may be desirable to transfer thermal energy (or heat) away from designated components of a system or device. Some systems use electrical components, such as electrical connectors, to transmit data and/or electrical power to and from different systems or devices. Some systems use electrical components, such as pluggable modules for transmitting data signals through communication cable(s) in the form of optical signals and/or electrical signals. Some systems use electrical components, such as integrated circuits, for controlling the system. The electrical components define heat generating sources within the system.

A common challenge that confronts developers of electrical systems is heat management. Thermal energy generated by electrical components within a system can degrade performance or even damage components of the system. To dissipate the thermal energy, systems include a thermal component, such as a heat sink, which engages the heat source, absorbs the thermal energy from the heat source, and transfers the thermal energy away. The heat sink is typically thermally coupled to another thermal component at yet another thermal interface. The components lose efficiency at each thermal interface. Additionally, it is difficult to achieve efficient thermal coupling at the interfaces due to limited thermal interface areas and variations in the surfaces, such as due to surface flatness of the interfacing surfaces.

Accordingly, there is a need for a thermal transfer assembly that efficiently transfers thermal energy away from an electrical component.

### BRIEF DESCRIPTION OF THE INVENTION

In one embodiment, a thermal bridge is provided and includes an upper bridge assembly including a plurality of upper plates arranged in an upper plate stack. Each upper plate is segmented including an upper forward segment at a front end of the upper plate and an upper rearward segment at a rear end of the upper plate. Each upper plate has an upper seam between the upper forward segment and the upper rearward segment. Each upper plate has sides between the front end and the rear end. Each upper plate has an inner end and an outer end. The thermal bridge includes a lower bridge assembly including a plurality of lower plates arranged in a lower plate stack. Each lower plate is segmented including a lower forward segment at a front end of the lower plate and a lower rearward segment at a rear end of the lower plate. Each lower plate has a lower seam between the lower forward segment and the lower rearward segment. Each lower plate has sides between the front end and the rear end. Each lower plate has an inner end and an outer end. The outer ends of the lower plates configured to face and thermally couple to an electrical component. The sides of some of the lower plates face the sides of some of the upper plates to thermally interface the lower plates with the upper plates. The thermal bridge includes a spring element positioned between the upper bridge assembly and the lower bridge assembly. The spring element includes an upper spring member engaging the upper plates to bias the upper plates with an opening force generally away from the lower plates. The spring element includes a lower spring member engaging the lower plates to bias the lower plates with an opening force generally away from the upper plates. The thermal bridge includes a bridge frame supporting the upper plates in the upper plate stack and supporting the lower plates in the lower plate stack. The bridge frame includes an upper open limit spar engaging the upper plates at the upper seam to limit spreading apart of the upper plates from the lower plates against the opening forces of the spring element. The bridge frame includes a lower open limit spar engaging the lower plates at the lower seam to limit spreading apart of the lower plates from the upper plates against the opening forces of the spring element.

In another embodiment, a thermal bridge is provided and includes an upper bridge assembly including a plurality of upper plates arranged in an upper plate stack. Each upper plate is segmented including an upper forward segment at a front end of the upper plate and an upper rearward segment at a rear end of the upper plate. Each upper plate has an upper seam between the upper forward segment and the upper rearward segment. Each upper plate has sides between the front end and the rear end. Each upper plate has an inner end and an outer end. The thermal bridge includes a lower bridge assembly including a plurality of lower plates arranged in a lower plate stack. Each lower plate is segmented including a lower forward segment at a front end of the lower plate and a lower rearward segment at a rear end of the lower plate. Each lower plate has a lower seam between the lower forward segment and the lower rearward segment. Each lower plate has sides between the front end and the rear end. Each lower plate has an inner end and an outer end. The outer ends of the lower plates configured to face and thermally couple to an electrical component. The sides of some of the lower plates face the sides of some of the upper plates to thermally interface the lower plates with the upper plates. The thermal bridge includes a spring element positioned between the upper bridge assembly and the lower bridge assembly at the upper seam and the lower seam. The spring element includes forward spring members engaging the upper forward segments and the lower forward segments to bias the upper forward segments and the lower forward segments away from each other with an opening force. The spring element includes rearward spring members engaging the upper rearward segments and the lower rearward segments to bias the upper rearward segments and the lower rearward segments away from each other with an opening force. The thermal bridge includes a bridge frame supporting the upper plates in the upper plate stack and supporting the lower plates in the lower plate stack to limit spreading apart of the upper and lower plates from each other against the opening forces of the spring element.

In a further embodiment, a thermal bridge is provided and includes an upper bridge assembly including a plurality of upper plates arranged in an upper plate stack. Each upper plate is segmented including an upper forward segment at a front end of the upper plate and an upper rearward segment at a rear end of the upper plate. Each upper plate has an upper seam between the upper forward segment and the upper rearward segment. Each upper plate has sides between the front end and the rear end. Each upper plate has an inner end and an outer end. The thermal bridge includes a lower bridge assembly including a plurality of lower plates arranged in a lower plate stack. Each lower plate is segmented including a lower forward segment at a front end of the lower plate and a lower rearward segment at a rear end of the lower plate. Each lower plate has a lower seam between the lower forward segment and the lower rearward segment. Each lower plate has sides between the front end and the rear end. Each lower plate has an inner end and an outer end. The outer ends of the lower plates configured to face and thermally couple to an electrical component. The sides of some of the lower plates face the sides of some of the upper plates to thermally interface the lower plates with the upper plates. The thermal bridge includes a spring element positioned between the upper bridge assembly and the lower bridge assembly at the upper seam and the lower seam. The spring element includes an upper spring member engaging the upper plates to bias the upper plates with an opening force generally away from the lower plates. The spring element includes a lower spring member engaging the lower plates to bias the lower plates with an opening force generally away from the upper plates. The thermal bridge includes a bridge frame supporting the upper plates in the upper plate stack and supporting the lower plates in the lower plate stack. The bridge frame includes an upper open limit spar aligned with the spring element at the upper seam. The upper open limit spar engages the upper plates at the upper seam to limit spreading apart of the upper plates from the lower plates against the opening forces of the spring element. The bridge frame includes a lower open limit spar aligned with the spring element at the upper seam and the lower seam. The lower open limit spar engages the lower plates at the lower seam to limit spreading apart of the lower plates from the upper plates against the opening forces of the spring element.

### BRIEF DESCRIPTION OF THE DRAWINGS

FIG. 1 is a front perspective view of a communication system and a thermal bridge in accordance with an exemplary embodiment for dissipating heat from at least one electrical component of the communication system.

FIG. 2 is an exploded view of the thermal bridge in accordance with an exemplary embodiment.

FIG. 3 illustrates various plate pairs, including upper plates and lower plates arranged relative to each other in the plate pairs in accordance with an exemplary embodiment.

FIG. 4 illustrates various plate pairs, including upper plates and lower plates arranged relative to each other in the plate pairs in accordance with an exemplary embodiment.

FIG. 5 is an enlarged view of a portion of the thermal bridge in accordance with an exemplary embodiment.

FIG. 6 is an enlarged view of a portion of the thermal bridge in accordance with an exemplary embodiment.

### DETAILED DESCRIPTION OF THE INVENTION

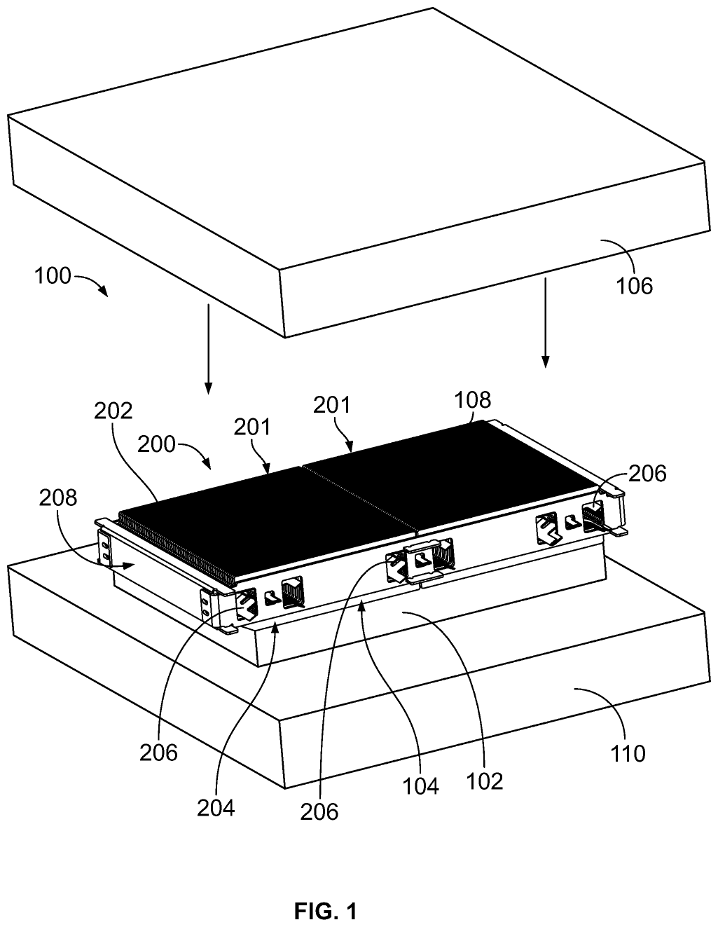

FIG. 1 is a front perspective view of a communication system 100 and a thermal bridge 200 in accordance with an exemplary embodiment for dissipating heat from at least one electrical component 102 of the communication system 100. The thermal bridge 200 is configured to be thermally coupled to the electrical component 102 at a lower thermal interface 104 at a bottom of the thermal bridge 200. In an exemplary embodiment, a heat transfer device 106 is provided to dissipate heat from the thermal bridge 200. For example, the thermal bridge 200 is configured to be thermally coupled to the heat transfer device 106 at an upper thermal interface 108. The thermal bridge 200 thermally connects the electrical component 102 and the heat transfer device 106 to dissipate heat from the electrical component 102. The heat transfer device 106 may be a heat sink, such as a finned heat sink, configured to be air cooled by transferring heat to the passing airflow. In other various embodiments, the heat transfer device 106 may be a heat spreader, a cold plate having liquid cooling, and the like.

In an exemplary embodiment, the thermal bridge 200 is compressible between the electrical component 102 and the heat transfer device 106. In an exemplary embodiment, the lower thermal interface 104 is conformable to a shape of the electrical component 102 and the upper thermal interface 108 is conformable to a shape of the heat transfer device 106 for efficient thermal transfer therebetween. For example, the thermal bridge 200 may be a stacked plate-like structure wherein the individual plates are movable relative to each other to conform to the electrical component 102 and the heat transfer device 106. In an exemplary embodiment, the thermal bridge 200 is segmented in the longitudinal direction into one or more segments 201 that are independently movable relative to each other and conformable to the electrical component 102 and/or the heat transfer device 106. For example, each of the plates is segmented into a forward segment and a rearward segment and possibly one or more intermediate segments between the forward and rearward segments.

In an exemplary embodiment, the electrical component 102 is mounted to a circuit board 110. In various embodiments, the electrical component 102 may be a communication connector, such as a receptacle connector, a header connector, a plug connector, or another type of communication connector. In other various embodiments, the electrical component 102 may be an electronic package, such as an integrated circuit. In other various embodiments, the electrical component 102 may be a pluggable module, such as an I/O transceiver module. Other types of electrical components may be provided in alternative embodiments.

In an exemplary embodiment, the thermal bridge 200 includes an upper bridge assembly 202, a lower bridge assembly 204, one or more spring elements 206 between the upper and lower bridge assemblies 202, 204, and a bridge frame 208 for holding the upper and lower bridge assemblies 202, 204 together. The lower bridge assembly 204 is configured to thermally engage the electrical component 102. The upper bridge assembly 202 is configured to dissipate heat into the external environment and/or to the heat transfer device 106. The upper bridge assembly 202 is in thermal communication with the lower bridge assembly 204 and dissipates heat away from the lower bridge assembly 204 to cool the electrical component 102. In an exemplary embodiment, the upper bridge assembly 202 is segmented into multiple segments 201 (for example, forward segment and rearward segment) and the lower bridge assembly 204 is segmented into multiple segments 201 (for example, forward segment and rearward segment).

The spring element(s) 206 biases the upper and lower bridge assemblies 202, 204 apart. In an exemplary embodiment, the spring elements 206 interface with the various segments 201 of the upper and lower bridge assemblies 202, 204 to spread the upper and lower segments 201 apart from each other by an opening force. The upper and lower bridge assemblies 202, 204 are compressible relative to each other. For example, the upper and lower segments 201 of the bridge assemblies 202, 204 are compressible between the electrical component 102 and the heat transfer device 106. The spring elements 206 are compressible between the upper and lower segments 201.

The bridge frame 208 provides support for the upper and lower bridge assemblies 202, 204. For example, the bridge frame 208 provides support for the upper and lower segments 201 of the bridge assemblies 202 204. The bridge frame 208 extends around an outer perimeter of the thermal bridge 200, such as along the sides and ends, leaving the top and bottom to form thermal interfaces with the electrical component 102 and the heat transfer device 106. In an exemplary embodiment, the bridge frame 208 provides internal support through the bridge assemblies 202, 204, such as through the segments 201. The internal support holds relative positions of the forward and rearward segments 201, such as by confining movement to a limited amount of relative movement to allow the segments 201 to conform to the electrical component 102 and the heat transfer device 106.

In an exemplary embodiment, the spring element 206 presses the segments 201 of the upper bridge assembly 202 outward in a first biasing direction (for example, upward) against the bridge frame 208 and the spring element 206 presses the segments 201 of the lower bridge assembly 204 outward in a second biasing direction (for example, downward) against the bridge frame 208. The upper bridge assembly 202 and the lower bridge assembly 204 may be held by the bridge frame 208 in a manner to allow a limited amount of floating movement of the upper bridge assembly 202 and the lower bridge assembly 204 relative to the bridge frame 208.

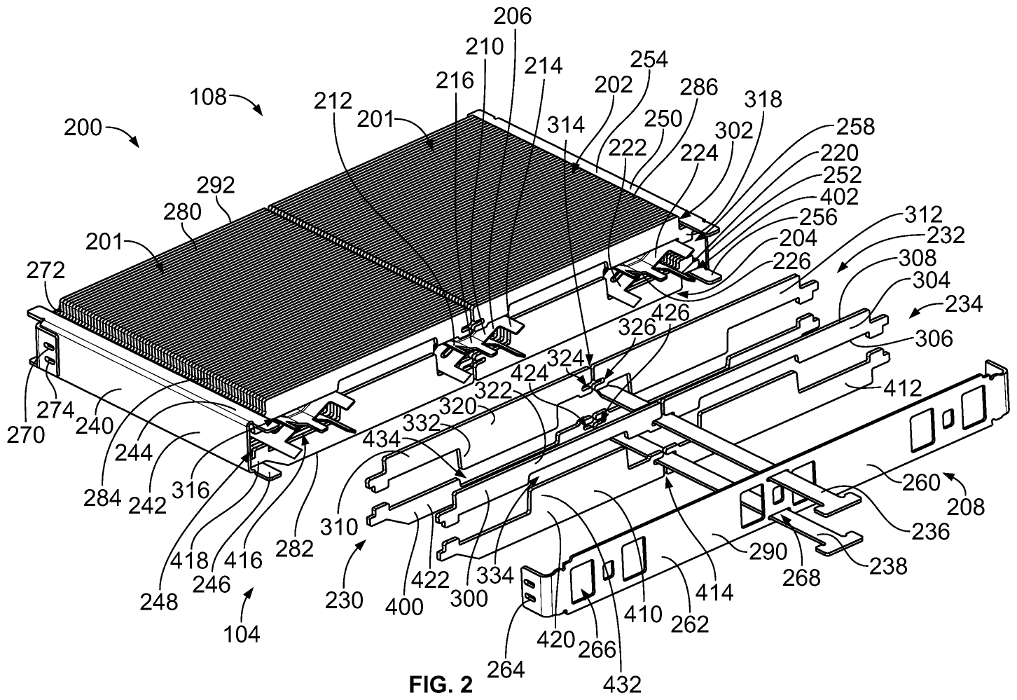

FIG. 2 is an exploded view of the thermal bridge 200 in accordance with an exemplary embodiment. The thermal bridge 200 includes the upper bridge assembly 202 and the lower bridge assembly 204. The spring element 206 is located between the upper and lower bridge assemblies 202, 204. The bridge frame 208 is configured to hold the upper and lower bridge assemblies 202, 204.

In an exemplary embodiment, the thermal bridge 200 is parallelepiped (for example, generally box shaped). For example, the thermal bridge 200 includes a top 280, a bottom 282, a front 284, a rear 286, a first side 290, and a second side 292. The thermal bridge 200 extends longitudinally between the front 284 and the rear 286. In an exemplary embodiment, the upper and lower bridge assemblies 202, 204 are segmented in the longitudinal direction into multiple segments 201 between the front 284 and the rear 286. The top 280 may be generally planar for thermal connection with the heat transfer device 106. The bottom 282 may be generally planar for thermal connection with the electrical component 102. The upper and lower bridge assemblies 202, 204 have a large surface area along the top 280 and the bottom 282 for thermal connection with the heat transfer device 102 and electrical component 106.

The bridge frame 208 is a frame structure used to hold the thermal bridge 200 together. The bridge frame 208 may extend along the front 284, the rear 286, the first side 290, and the second side 292 to hold the upper and lower bridge assemblies 202, 204 together in the interior of the bridge frame 208. In an exemplary embodiment, no portion of the bridge frame 208 extends along the top 280 or the bottom 282. The bridge frame 208 is remote from the upper thermal interface 108 such that the bridge frame 208 does not obstruct the upper thermal interface 108 and provides a large amount of usable external surface area for interfacing with the heat transfer device 106. The bridge frame 208 is remote from the lower thermal interface 104 such that the bridge frame 208 does not obstruct the lower thermal interface 104 and provides a large amount of usable external surface area for interfacing with the electrical component 102.

In an exemplary embodiment, the bridge assemblies 202, 204 each include a plurality of plates that are arranged together in plate stacks. In an exemplary embodiment, each of the plates is segmented in the longitudinal direction into multiple plate segments 201 between the front 284 and the rear 286. The plates and plate segments 201 are interleaved with each other for thermal communication between the upper bridge assembly 202 and the lower bridge assembly 204. The individual plates and plate segments 201 are movable relative to each other such that the plates may be individually articulated to conform to the electrical component 102 and/or the heat transfer device 106. For example, the individual plates may conform to the electrical component 102 at the lower thermal interface 104 for improved contact and/or proximity between the thermal bridge 200 and the electrical component 102 and/or the individual plates may conform to the heat transfer device 106 at the upper thermal interface 108 for improved contact and/or proximity between the thermal bridge 200 and the heat transfer device 106. A gap or space may be provided between the plates and plate segments 201 of the upper and lower bridge assemblies 202, 204 to allow compressive movement of the spring element 206 between the bridge assemblies 202, 204.

In an exemplary embodiment, the upper bridge assembly 202 includes a plurality of upper plates 300 arranged in an upper plate stack 302. Each upper plate 300 has sides 304 extending between an inner end 306 and an outer end 308 of the upper plate 300. The inner end 306 faces the lower bridge assembly 204. The outer end 308 faces outward, such as toward the heat transfer device 106. Optionally, various upper plates 300 may have different shapes, such as different heights and/or different features between the inner end 306 and the outer end 308. In an exemplary embodiment, each upper plate 300 includes an upper forward segment 310 and an upper rearward segment 312. An upper seam 314 is defined between the upper forward segment 310 and the upper rearward segment 312. The upper forward and rearward segments 310, 312 are connected together across the upper seam 314 by the bridge frame 208 to control relative movement between the upper forward and rearward segments 310, 312. Additional intermediate segments (not shown) may be arranged between the upper forward and rearward segments 310, 312 with additional upper seams therebetween.

In an exemplary embodiment, the lower bridge assembly 204 includes a plurality of lower plates 400 arranged in a lower plate stack 402. Each lower plate 400 has sides 404 extending between an inner end 406 and an outer end 408 of the lower plate 400. The inner end 406 faces the upper bridge assembly 202. The outer end 408 faces outward, such as toward the electrical component 102 (shown in FIG. 1). Optionally, various lower plates 400 may have different shapes and/or heights between the inner end 406 and the outer end 408. In an exemplary embodiment, each lower plate 400 includes a lower forward segment 410 and a lower rearward segment 412. A lower seam 414 is defined between the lower forward segment 410 and the lower rearward segment 412. The lower forward and rearward segments 410, 412 are connected together across the lower seam 414 by the bridge frame 208 to control relative movement between the lower forward and rearward segments 410, 412. Additional intermediate segments (not shown) may be arranged between the lower forward and rearward segments 410, 412 with additional lower seams therebetween.

In an exemplary embodiment, the upper and lower plates 300, 400 are arranged in plate pairs 230. Each plate pair 230 includes one of the upper plates 300 and one of the lower plates 400. The plates 300, 400 in the plate pair 230 are aligned with each other. For example, the upper and lower plates 300, 400 are vertically stacked with the upper plate 300 above the lower plate 400. The plate pairs 230 are stacked together to form the thermal bridge 200 in the stacked arrangement. The bridge frame 208 holds the plate pairs 230 in the stacked arrangement. The spring element 206 is configured to be positioned between the upper and lower plates 300, 400 and spread the upper plates 300 apart from the lower plates 400.

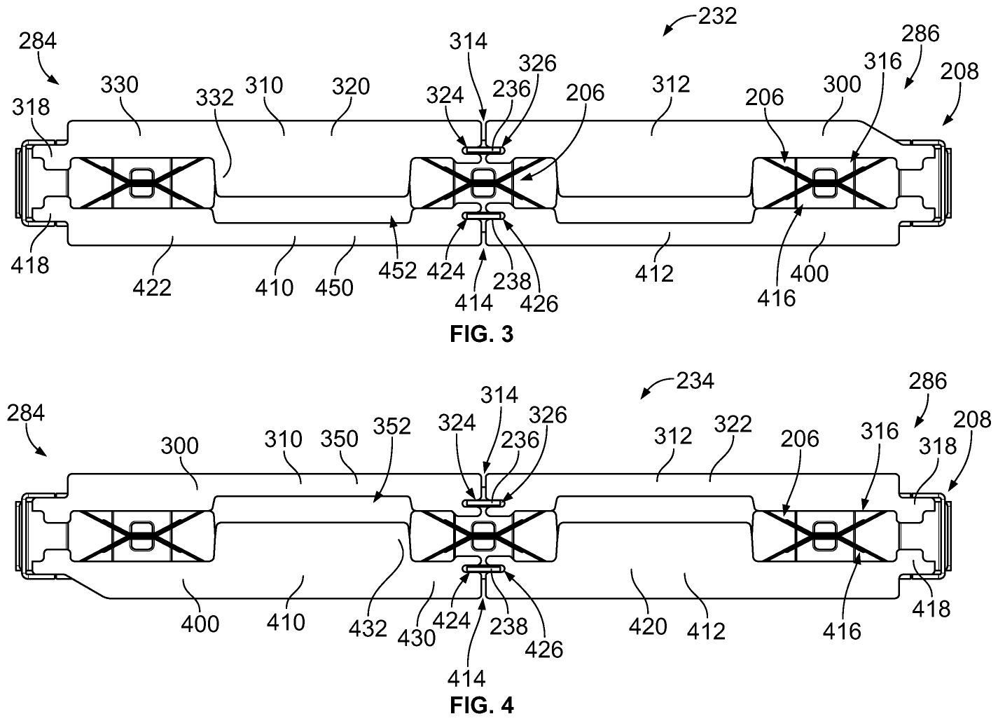

With additional reference to FIGS. 3 and 4, FIGS. 3 and 4 illustrate various plate pairs 230, including upper plates 300 and lower plates 400 arranged relative to each other in the plate pairs 230. FIG. 3 shows a first pair 232. FIG. 4 shows a second pair 234. The upper plates 300 of the first pair 232 are different from the upper plates 300 of the second pair 234. The lower plates 400 of the first pair 232 are different from the lower plates 400 of the second pair 234.

In an exemplary embodiment, the upper plates 300 include upper spring pockets 316 that receive the spring elements 206. The upper spring pockets 316 may be located proximate to the front end and the rear end. The upper spring pockets 316 may be located at the upper seam 314 to allow the spring elements 206 to engage the upper forward and rearward segments 310, 312.

In an exemplary embodiment, the lower plates 400 include lower spring pockets 416 that receive the spring elements 206. The lower spring pockets 416 may be located proximate to the front end and the rear end. The lower spring pockets 416 may be located at the lower seam 414 to allow the spring elements 206 to engage the lower forward and rearward segments 410, 412.

In an exemplary embodiment, the upper plates 300 include upper limit tabs 318 used to position the upper plates 300 relative to the bridge frame 208. For example, the upper limit tabs 318 are provided at the front and rear ends of the upper plates 300 to interface with the bridge frame 208, such as at the front 284 and the rear 286. The upper limit tabs 318 engage the bridge frame 208 to position the upper plates 300 in the upper plate stack 302. The upper limit tabs 318 limit vertical movement of the upper plates 300, such as to limit spreading apart of the upper plates 300 from the lower plates 400. The spring element 206 may press the upper plates 300 outward (for example, upward) until the upper limit tabs 318 bottom out against the bridge frame 208.

In an exemplary embodiment, the lower plates 400 include lower limit tabs 418 used to position the lower plates 400 relative to the bridge frame 208. For example, the lower limit tabs 418 are provided at the front and rear ends of the lower plates 400 to interface with the bridge frame 208, such as at the front 284 and the rear 286. The lower limit tabs 418 engage the bridge frame 208 to position the lower plates 400 in the lower plate stack 402. The lower limit tabs 418 limit vertical movement of the lower plates 400, such as to limit spreading apart of the lower plates 400 from the upper plates 300. The spring element 206 may press the lower plates 400 outward (for example, upward) until the lower limit tabs 418 bottom out against the bridge frame 208.

In an exemplary embodiment, the upper plates 300 include upper bridge plates 320 (FIG. 3) and upper spacer plates 322 (FIG. 4). The upper spacer plates 322 are located between the upper bridge plates 320. The upper bridge plates 320 and the upper spacer plates 322 both include upper limit tabs 318. In an exemplary embodiment, the lower plates 400 include lower bridge plates 420 (FIG. 4) and lower spacer plates 422 (FIG. 3). The lower spacer plates 422 are located between the lower bridge plates 420. The lower bridge plates 420 and the lower spacer plates 422 both include lower limit tabs 418.

With reference to FIG. 3, each upper bridge plate 320 includes a base 330 at the outer end 308 and overlapping regions 332 at the inner end 306 configured to overlap with adjacent lower plates 400 of the lower bridge assembly 204. The overlapping regions 332 extend downward from the base 330. The upper bridge plate 320 is wider at the overlapping regions 332 than along the base 330. The overlapping regions 332 provide large surface areas configured to be thermally coupled to the adjacent lower plates 400. The overlapping regions 332 are located between the upper spring pockets 316. In the illustrated embodiment, the upper forward segment 310 includes a corresponding overlapping region 332 and the upper rearward segment 312 includes a corresponding overlapping region 332.

Each lower spacer plate 422 includes a spacer base 450 at the outer end 408 and pockets 452 formed in the spacer base 450. The pockets 452 are aligned with and configured to receive the corresponding overlapping regions 332 of the upper plates 300. The lower spacer plate 422 is thinner along the pockets 452 than along the spacer base 450. The pockets 452 are located between the lower spring pockets 416. In the illustrated embodiment, the lower forward segment 410 includes a corresponding pocket 452 and the lower rearward segment 412 includes a corresponding pocket 452.

With reference to FIG. 4, each upper spacer plate 322 includes a spacer base 350 at the outer end 308 and pockets 352 formed in the spacer base 350. The pockets 352 are aligned with and configured to receive overlapping regions of the lower plates 400. The upper spacer plate 322 is thinner along the pockets 352 than along the spacer base 350. The pockets 352 are located between the upper spring pockets 316. In the illustrated embodiment, the upper forward segment 310 includes a corresponding pocket 352 and the upper rearward segment 312 includes a corresponding pocket 352.

Each lower bridge plate 420 includes a base 430 at the outer end 408 and overlapping regions 432 at the inner end 406 configured to overlap with adjacent upper plates 300 of the upper bridge assembly 202. The overlapping regions 432 extend upward from the base 430. The lower bridge plate 420 is wider at the overlapping regions 432 than along the base 430. The overlapping regions 432 provide large surface areas configured to be thermally coupled to the adjacent upper plates 300, such as the overlapping regions 332. The overlapping regions 432 are located between the lower spring pockets 416. In the illustrated embodiment, the lower forward segment 410 includes a corresponding overlapping region 432 and the lower rearward segment 412 includes a corresponding overlapping region 432.

With reference back to FIG. 2, the spring element 206 is separate and discrete from the upper and lower bridge assemblies 202, 204. The spring element 206 may be a stamped and formed part. The spring element 206 is manufactured from a thin metal material such that the spring element 206 is flexible. In an exemplary embodiment, the spring element 206 includes an upper spring member 210 and a lower spring member 220. The upper spring member 210 engages the upper plates 300 to bias the upper plates 300 with an opening force generally away from the lower plates 400. The lower spring member 220 engages the lower plates 400 to bias the lower plates 400 with an opening force generally away from the upper plates 300. The upper spring member 210 may be separate and discrete from the lower spring member 220 and coupled thereto to form the spring element 206. In the illustrated embodiment, the spring plates 210 are cupped leaf springs arranged back-to-back to form the spring element 206. For example, the spring element 206 may be X-shaped. Other types of spring elements 206 may be used in alternative embodiments, such as coil springs, leaf springs, C-shaped channel springs, and the like.

The upper spring member 210 includes forward spring members 212 and rearward spring members 214. The upper spring member 210 may include a central panel 216 between the forward and rearward spring members 212, 214. Distal ends of the forward and rearward spring members 212, 214 are configured to engage the upper forward segments 310 and the upper rearward segments 312, respectively, of the upper plates 300. The spring members 212, 214 may include individual spring fingers.

The lower spring member 220 includes forward spring members 222 and rearward spring members 224. The lower spring member 220 may include a central panel 226 between the forward and rearward spring members 222, 224. Distal ends of the forward and rearward spring members 222, 224 are configured to engage the lower forward segments 310 and the lower rearward segments 312, respectively, of the lower plates 300. The spring members 222, 224 may include individual spring fingers.

The spring element 206 is configured to be received in the upper and lower spring pockets 316, 416. The spring element 206 is located between the upper plates 300 and the lower plates 400. The spring elements 206 are compressible between the upper plates 300 and the lower plates 400. Any number of spring elements 206 may be provided depending on the amount of spring force required, the spacing between the upper plates 300 and the lower plates 400, the lengths of the upper plates 300 and the lower plates 400, and the number of segments of the upper plates 300 and the lower plates 400. In the illustrated embodiment, the thermal bridge 200 includes a forward spring element proximate to the front 284, a rearward spring element proximate to the rear 286, and a central spring element at the seam between the forward and rearward segments of the plates.

In an exemplary embodiment, the bridge frame 208 is manufactured from a plurality of frame elements, which may be connected together to form a supporting structure for the upper and lower segments 201 of the upper and lower plates 300, 400. For example, the frame elements may surround the outer perimeter of the plate stacks. The frame elements may pass through the interior of the plate stacks to hold the segments 201. In an exemplary embodiment, the bridge frame 208 includes a front rail 240, a rear rail 250, a first side rail 260 extending between the front and rear rails 240, 250, and a second side rail 270 extending between the front and rear rails 240, 250. In an exemplary embodiment, the bridge frame 208 includes an upper open limit spar 236 and a lower open limit spar 238. The upper and lower open limit spars 236, 238 extend through the plate stacks between the first and second side rails 260, 270. The upper open limit spars 238 engage the upper plates 300 to limit spreading apart of the upper plates 300 from the lower plates 400 against the opening forces of the spring element 206. The lower open limit spar 238 engages the lower plates 400 to limit spreading apart of the lower plates 400 from the upper plates 300 against the opening forces of the spring element 206. In an exemplary embodiment, the upper and lower open limit spars 236, 238 are located at the seams 314, 414 to support the forward and rearward segments 201 relative to each other.

The front rail 240 includes a main panel 242 and upper and lower flanges 244, 246 extending from the main panel 242. The front rail 240 may be stamped and formed from a metal sheet. A space 248 is defined between the flanges 244, 246 that receives the ends of the plates 300, 400. For example, the upper and lower limit tabs 318, 418 at the front ends of the plates 300, 400 are received in the space 248. The flanges 244, 246 are configured to capture the upper and lower limit tabs 318, 418 in the space 248. The flanges 244, 246 limit spreading apart of the upper and lower plates 300, 400. The upper limit tabs 318 at the front ends engage the upper flange 244 to limit spreading apart (upward movement) of the upper plates 300 at the front end. The lower limit tabs 418 at the front ends engage the lower flange 246 to limit spreading apart (downward movement) of the lower plates 400 at the front end. The front spring element 206 is located at the front ends of the plates 300, 400, such as proximate to the front rail 240 to bias the segments 201 of the plates 300, 400 apart from each other.

The rear rail 250 includes a main panel 252 and upper and lower flanges 254, 256 extending from the main panel 252. The rear rail 250 may be stamped and formed from a metal sheet. A space 258 is defined between the flanges 254, 256 that receives the ends of the plates 300, 400. For example, the upper and lower limit tabs 318, 418 at the rear ends of the plates 300, 400 are received in the space 258. The flanges 254, 256 are configured to capture the upper and lower limit tabs 318, 418 in the space 258. The flanges 254, 256 limit spreading apart of the upper and lower plates 300, 400. The upper limit tabs 318 at the rear ends engage the upper flange 254 to limit spreading apart (upward movement) of the upper plates 300 at the rear end. The lower limit tabs 418 at the rear ends engage the lower flange 256 to limit spreading apart (downward movement) of the lower plates 400 at the rear end. The rear spring element 206 is located at the rear ends of the plates 300, 400, such as proximate to the rear rail 250 to bias the segments 201 of the plates 300, 400 apart from each other.

The first side rail 260 includes a main panel 262 and connecting tabs 264 extending from the main panel 262 to connect the first side rail 260 to the front and rear rails 240, 250. The connecting tabs 264 may be soldered or welded to the front and rear rails 240, 250. The first side rail 260 may be stamped and formed from a metal sheet. The main panel 262 includes openings 266 that receive locating tabs at ends of the spring elements 206. The main panel 262 includes slots 268 that receive the upper and lower open limit spars 236, 238. The ends of the upper and lower open limit spars 236, 238 are supported by the first side rail 260 within the slots 268. The upper and lower open limit spars 236, 238 may be soldered or welded to the first side rail 260 to secure the upper and lower open limit spars 236, 238 to the first side rail 260.

The second side rail 270 includes a main panel 272 and connecting tabs 274 extending from the main panel 272 to connect the second side rail 270 to the front and rear rails 240, 250. The connecting tabs 274 may be soldered or welded to the front and rear rails 240, 250. The second side rail 270 may be stamped and formed from a metal sheet. The main panel 272 includes openings (not shown) that receive locating tabs at ends of the spring elements 206. The main panel 272 includes slots (not shown) that receive the upper and lower open limit spars 236, 238. The ends of the upper and lower open limit spars 236, 238 are supported by the second side rail 270 within the slots. The upper and lower open limit spars 236, 238 may be soldered or welded to the second side rail 270 to secure the upper and lower open limit spars 236, 238 to the second side rail 270.

In an exemplary embodiment, the upper open limit spar 236 is a flat, planar spar configured to pass through the upper plates 300. The upper open limit spar 236 may be generally rectangular in cross-section. For example, the opposite ends of the flat spar may be received in the upper forward segment 310 and the upper rearward segment 312. In an exemplary embodiment, the upper open limit spar 236 is located at the upper seam 314. The upper forward and rearward segments 310, 312 are connected together across the upper seam 314 by the upper open limit spar 236 to control relative movement between the upper forward and rearward segments 310, 312. In an exemplary embodiment, each upper forward segment 310 includes an upper slot 324 and each upper rearward segment 312 includes an upper slot 326. The upper slots 324, 326 are generally aligned with each other. The upper slots 326 are open to the upper seam 314. The upper slots 324, 326 receive the upper open limit spar 236. In an exemplary embodiment, the upper slots 324, 326 are oversized relative to the upper open limit spar 236 forming a clearance gap in the upper slots 324, 326 sized to allow floating movement of the upper forward segment 310 and the upper rearward segment 312 in the upper slots 324, 326, such as to allow compression and expansion of the upper plates 300 relative to the lower plates 400 and to allow the upper plates 300 to conform to the heat transfer device 106. The upper open limit spar 236 may be stamped and formed from a metal sheet. However, other types of connecting element may be used in alternative embodiments. For example, the connecting element may be round or square pins that may be manufactured by an extrusion process. Other types of connecting elements may be used in alternative embodiments.

In an exemplary embodiment, the lower open limit spar 238 is a flat, planar spar configured to pass through the lower plates 400. The lower open limit spar 238 may be generally rectangular in cross-section. For example, the opposite ends of the flat spar may be received in the lower forward segment 410 and the lower rearward segment 412. In an exemplary embodiment, the lower open limit spar 238 is located at the lower seam 414. The lower forward and rearward segments 410, 412 are connected together across the lower seam 414 by the lower open limit spar 238 to control relative movement between the lower forward and rearward segments 410, 412. In an exemplary embodiment, each lower forward segment 410 includes a lower slot 424 and each lower rearward segment 412 includes a lower slot 426. The lower slots 424, 426 are generally aligned with each other. The lower slots 426 are open to the lower seam 414. The lower slots 424, 426 receive the lower open limit spar 238. In an exemplary embodiment, the lower slots 424, 426 are oversized relative to the lower open limit spar 238 forming a clearance gap in the lower slots 424, 426 sized to allow floating movement of the lower forward segment 410 and the lower rearward segment 412 in the lower slots 424, 426, such as to allow compression and expansion of the lower plates 400 relative to the upper plates 300 and to allow the lower plates 400 to conform to the electrical component 102. The lower open limit spar 238 may be stamped and formed from a metal sheet. However, other types of connecting element may be used in alternative embodiments. For example, the connecting element may be round or square pins that may be manufactured by an extrusion process. Other types of connecting elements may be used in alternative embodiments.

When assembled, the spring element 206 is located between the upper and lower plates 300, 400. The spring elements 206 bias the upper and lower plates 300, 400 apart. For example, the spring elements 206 bias the segments 210 apart. The upper and lower open limit spars 236, 238 control positioning of the upper and lower plates 300, 400 in the plate stacks. For example, the upper and lower open limit spars 236, 238 limit spreading apart of the upper and lower plates 300, 400 at a predetermined outer limit. The spring element 206 is compressible between the upper and lower plates 300, 400, such as when mated with the electrical component 102 and the heat transfer device 106.

When assembled, the lower spacer plate 422 is aligned with the upper bridge plate 320 and the upper spacer plate 322 is aligned with the lower bridge plate 420. The overlapping regions 332 are vertically aligned with the pockets 434. Similarly, the overlapping regions 432 are vertically aligned with the pockets 334. The overlapping regions 332, 432 are arranged side-by-side within the upper and lower stacks to allow thermal transfer between the upper and lower plates 300, 400.

The spring element 206 is received in the gaps between the upper and lower segments 201 of the plates 300, 400. The spring element 206 presses the segments of the upper plate 300 in an upward biasing direction and presses the segments of the lower plate 400 in a downward biasing direction. The spring element 206 tends to separate the segments of the upper plate 300 from the segments of the lower plate 400 to press the upper plates 300 into thermal engagement with the heat transfer device 106 and to press the lower plates 400 into thermal engagement with the electrical component 102. The segments 201 of upper plates 300 and the lower plates 400 are independently movable relative to each other and relative to adjacent segments 201 of the upper plates 300 and lower plates 400. The segments of the upper plates 300 are configured to float relative to the segments of the lower plates 400 and the spring elements 206 allow the floating movement of the upper plates 300 and the lower plates 400. As such, the upper mating interface is conformable to the heat transfer device 106 and the lower mating interface is conformable to the electrical component 102.

The bridge frame 208 holds the upper plates 300 and the lower plates 400. The upper and lower open limit spars 236, 238 extend between the side rails 260, 270 and pass through the upper and lower slots 326, 426 (for example, through the entire stack). The limit tabs defining the slots 326, 426 interface with the upper and lower open limit spars 236, 238 to position the upper and lower plates 300, 400 relative to each other and define outer spreading limits of the upper and lower plates 300, 400 relative to each other. For example, the limit tabs form stop surfaces that engage the upper and lower open limit spars 236, 238. The upper and lower open limit spars 236, 238 limit spreading apart of the upper and lower plates 300, 400 from each other. The spring element 206 presses the upper plates 300 upward until the stop surfaces engage the upper open limit spars 238. The spring element 206 presses the lower plates 400 downward until the stop surfaces engage the lower open limit spars 238.

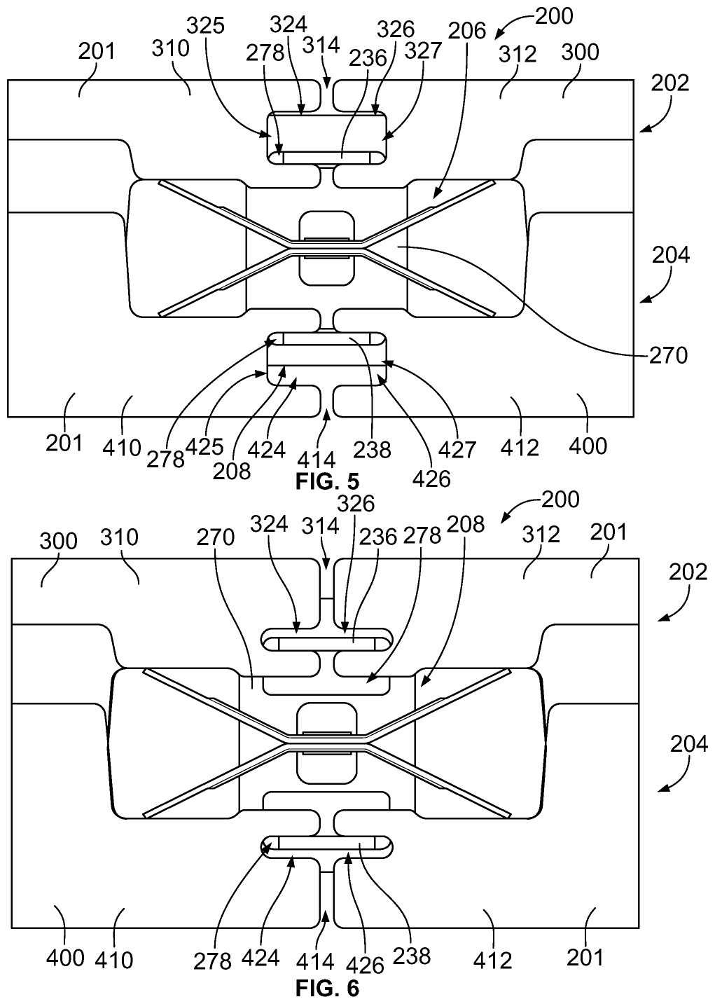

FIG. 5 is an enlarged view of a portion of the thermal bridge 200 in accordance with an exemplary embodiment. The thermal bridge 200 includes the upper bridge assembly 202 and the lower bridge assembly 204 with the spring element 206 located between the upper and lower bridge assemblies 202, 204. The bridge frame 208 is configured to hold the upper and lower bridge assemblies 202, 204, such as at the seam 314, 414 between the segmented plates 300, 400 of the upper and lower bridge assemblies 202, 204. In an exemplary embodiment, the spring element 206 is located in between the plate segments 201 at the seam 314, 414.

In an exemplary embodiment, the bridge frame 208 is used to hold the plates 300, 400 in the plate stacks. The bridge frame 208 is used to hold the spring element 206. A portion of the side rail 270 is shown in FIG. 5 supporting the upper open limit spar 236 and the lower open limit spar 238. For example, the side rail 270 includes slots 278 that receive the upper and lower open limit spars 236, 238. The upper and lower open limit spars 236, 238 may be soldered or welded to the second side rail 270 to secure the upper and lower open limit spars 236, 238 to the second side rail 270.

The upper and lower open limit spars 236, 238 extend through the plate stacks. The upper open limit spars 238 engage the upper plates 300 to limit spreading apart of the upper plates 300 from the lower plates 400 against the opening forces of the spring element 206. The lower open limit spar 238 engages the lower plates 400 to limit spreading apart of the lower plates 400 from the upper plates 300 against the opening forces of the spring element 206. In an exemplary embodiment, the upper and lower open limit spars 236, 238 are located at the seams 314, 414 to support the forward and rearward segments 201 relative to each other.

In an exemplary embodiment, the upper open limit spar 236 is located at the upper seam 314. The upper forward and rearward segments 310, 312 are connected together across the upper seam 314 by the upper open limit spar 236 to control relative movement between the upper forward and rearward segments 310, 312. In an exemplary embodiment, the upper slots 324, 326 of the upper forward segment 310 and the upper rearward segment 312 receive the upper open limit spar 236. In an exemplary embodiment, the upper slots 324, 326 are oversized relative to the upper open limit spar 236 forming clearance gaps 325, 327 in the upper slots 324, 326 sized to allow floating movement of the upper forward segment 310 and the upper rearward segment 312 relative to the upper open limit spar 236, such as to allow compression and expansion of the upper plates 300 relative to the lower plates 400 and to allow the upper plates 300 to conform to the heat transfer device 106.

In an exemplary embodiment, the lower open limit spar 238 is located at the lower seam 414. The lower forward and rearward segments 410, 412 are connected together across the lower seam 414 by the lower open limit spar 238 to control relative movement between the lower forward and rearward segments 410, 412. In an exemplary embodiment, the lower slots 424, 426 of the lower forward segment 410 and the lower rearward segment 412 receive the lower open limit spar 238. In an exemplary embodiment, the lower slots 424, 426 are oversized relative to the lower open limit spar 238 forming clearance gaps 425, 427 in the lower slots 424, 426 sized to allow floating movement of the lower forward segment 410 and the lower rearward segment 412 relative to the lower open limit spar 238, such as to allow compression and expansion of the lower plates 400 relative to the upper plates 300 and to allow the lower plates 400 to conform to the electrical component 102.

When assembled, the spring element 206 is located between the upper and lower plates 300, 400. The spring element 206 biases the upper and lower plates 300, 400 apart. For example, the spring element 206 biases the segments 210 apart. The upper and lower open limit spars 236, 238 control positioning of the upper and lower plates 300, 400 in the plate stacks. For example, the upper and lower open limit spars 236, 238 limit spreading apart of the upper and lower plates 300, 400 at a predetermined outer limit. The spring element 206 is compressible between the upper and lower plates 300, 400, such as when mated with the electrical component 102 and the heat transfer device 106. The spring element 206 is received in the gaps between the upper and lower segments 201 of the plates 300, 400. The spring element 206 presses the segments of the upper plate 300 in an upward biasing direction and presses the segments of the lower plate 400 in a downward biasing direction. The spring element 206 tends to separate the segments of the upper plate 300 from the segments of the lower plate 400 to press the upper plates 300 into thermal engagement with the heat transfer device 106 and to press the lower plates 400 into thermal engagement with the electrical component 102. The segments 201 of upper plates 300 and the lower plates 400 are independently movable relative to each other and relative to adjacent segments 201 of the upper plates 300 and lower plates 400. The segments of the upper plates 300 are configured to float relative to the segments of the lower plates 400 and the spring elements 206 allow the floating movement of the upper plates 300 and the lower plates 400. As such, the upper mating interface is conformable to the heat transfer device 106 and the lower mating interface is conformable to the electrical component 102.

The bridge frame 208 holds the upper plates 300 and the lower plates 400. The upper and lower open limit spars 236, 238 extend between the side rails 260, 270 and pass through the upper and lower slots 326, 426 (for example, through the entire stack). The limit tabs defining the slots 326, 426 interface with the upper and lower open limit spars 236, 238 to position the upper and lower plates 300, 400 relative to each other and define outer spreading limits of the upper and lower plates 300, 400 relative to each other. The upper and lower open limit spars 236, 238 limit spreading apart of the upper and lower plates 300, 400 from each other. The spring element 206 presses the upper plates 300 upward until the stop surfaces or flanges forming the slots 324, 326 engage the upper open limit spar 236. The spring element 206 presses the lower plates 400 downward until the stop surfaces or flanges forming the slots 424, 426 engage the lower open limit spar 238.

FIG. 6 is an enlarged view of a portion of the thermal bridge 200 in accordance with an exemplary embodiment. The thermal bridge 200 includes the upper bridge assembly 202 and the lower bridge assembly 204 with the spring element 206 located between the upper and lower bridge assemblies 202, 204. The bridge frame 208 is configured to hold the upper and lower bridge assemblies 202, 204, such as at the seam 314, 414 between the segmented plates 300, 400 of the upper and lower bridge assemblies 202, 204. In an exemplary embodiment, the spring element 206 is located in between the plate segments 201 at the seam 314, 414. The thermal bridge 200 shown in FIG. 6 is similar to the thermal bridge 200 shown in FIG. 5. However, the size of the clearance gaps in the slots 324, 326, 424, 426 is shorter in the embodiment shown in FIG. 6. The size of the slots 278 in the side rail 270 are taller in the embodiment shown in FIG. 6 allowing floating movement of the upper and lower open limit spars 236, 238 relative to the side rail 270 to allow floating movement of the plates relative to the bridge frame 208.

In an exemplary embodiment, the bridge frame 208 is used to hold the plates 300, 400 in the plate stacks. The bridge frame 208 is used to hold the spring element 206. A portion of the side rail 270 is shown in FIG. 6 supporting the upper open limit spar 236 and the lower open limit spar 238. The upper and lower open limit spars 236, 238 extend through the plate stacks. The upper open limit spars 238 engage the upper plates 300 to limit spreading apart of the upper plates 300 from the lower plates 400 against the opening forces of the spring element 206. The lower open limit spar 238 engages the lower plates 400 to limit spreading apart of the lower plates 400 from the upper plates 300 against the opening forces of the spring element 206. In an exemplary embodiment, the upper and lower open limit spars 236, 238 are located at the seams 314, 414 to support the forward and rearward segments 201 relative to each other.

In an exemplary embodiment, the upper open limit spar 236 is located at the upper seam 314. The upper forward and rearward segments 310, 312 are connected together across the upper seam 314 by the upper open limit spar 236 to control relative movement between the upper forward and rearward segments 310, 312. In an exemplary embodiment, the upper slots 324, 326 of the upper forward segment 310 and the upper rearward segment 312 receive the upper open limit spar 236. The upper open limit spar 236 is positioned in the upper slots 234, 236 and received in the slot 278 in the side rail 270. The upper open limit spar 236 is configured to move vertically in the slot 278, such as to allow compression and expansion of the upper plates 300 relative to the lower plates 400 and to allow the upper plates 300 to conform to the heat transfer device 106.

In an exemplary embodiment, the lower open limit spar 238 is located at the lower seam 414. The lower forward and rearward segments 410, 412 are connected together across the lower seam 414 by the lower open limit spar 238 to control relative movement between the lower forward and rearward segments 410, 412. In an exemplary embodiment, the lower slots 424, 426 of the lower forward segment 410 and the lower rearward segment 412 receive the lower open limit spar 238. The lower open limit spar 238 is positioned in the lower slots 424, 426 and received in the slot 278 in the side rail 270. The lower open limit spar 238 is configured to move vertically in the slot 278, such as to allow compression and expansion of the lower plates 400 relative to the upper plates 300 and to allow the lower plates 400 to conform to the electrical component 102.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112 (f), unless and until such claim limitations expressly use the phrase “means for” followed by a statement of function void of further structure.

What is claimed is:

1. A thermal bridge comprising:
an upper bridge assembly including a plurality of upper plates arranged in an upper plate stack, each upper plate being segmented including an upper forward segment at a front end of the upper plate and an upper rearward segment at a rear end of the upper plate, each upper plate having an upper seam between the upper forward segment and the upper rearward segment, each upper plate having sides between the front end and the rear end, each upper plate having an inner end and an outer end;
a lower bridge assembly including a plurality of lower plates arranged in a lower plate stack, each lower plate being segmented including a lower forward segment at a front end of the lower plate and a lower rearward segment at a rear end of the lower plate, each lower plate having a lower seam between the lower forward segment and the lower rearward segment, each lower plate having sides between the front end and the rear end, each lower plate having an inner end and an outer end, the outer ends of the lower plates configured to face and thermally couple to an electrical component, the sides of some of the lower plates facing the sides of some of the upper plates to thermally interface the lower plates with the upper plates;
a spring element positioned between the upper bridge assembly and the lower bridge assembly, the spring element including an upper spring member engaging the upper plates to bias the upper plates with an opening force generally away from the lower plates, the spring element including a lower spring member engaging the lower plates to bias the lower plates with an opening force generally away from the upper plates; and
a bridge frame supporting the upper plates in the upper plate stack and supporting the lower plates in the lower plate stack, the bridge frame including an upper open limit spar engaging the upper plates at the upper seam to limit spreading apart of the upper plates from the lower plates against the opening forces of the spring element, the bridge frame including a lower open limit spar engaging the lower plates at the lower seam to limit spreading apart of the lower plates from the upper plates against the opening forces of the spring element.

2. The thermal bridge of claim 1, wherein the upper forward segment and the upper rearward segment include upper slots receiving the upper open limit spar, the lower forward segment and the lower rearward segment include lower slots receiving the lower open limit spar.

3. The thermal bridge of claim 2, wherein the upper slots are open to the upper seam, the lower slots being open to the lower seam.

4. The thermal bridge of claim 2, wherein the upper slots are oversized relative to the upper spar forming a clearance gap sized to allow floating movement of the upper forward segment and the upper rearward segment in the upper slots to allow compression and expansion of the upper plates relative to the lower plates, the lower slots being oversized relative to the lower spar forming a clearance gap sized to allow floating movement of the lower forward segment and the lower rearward segment in the lower slots to allow compression and expansion of the lower plates relative to the upper plates.

5. The thermal bridge of claim 1, wherein the bridge frame includes a first side rail at a first side of the thermal bridge and a second side rail at a second side of the thermal bridge, the upper and lower open limit spars extending between the first and second side rails.

6. The thermal bridge of claim 1, wherein the first and second side rails include slots receiving the upper and lower open limit spars, the slots being oversized relative to the upper and lower open limit spars to allow vertical movement of the upper and lower limit spars in the slots to allow floating movement of the upper and lower open limit spars relative to the first and second side rails to allow compression and expansion of the upper and lower plates relative to the bridge frame.

7. The thermal bridge of claim 1, wherein the spring element is aligned with the upper and lower open limit slots at the upper and lower seams.

8. The thermal bridge of claim 1, wherein the upper open limit spar limits movement of the upper forward section relative to the upper rearward sections, the lower open limit spar limits movement of the lower forward section relative to the lower rearward sections.

9. The thermal bridge of claim 1, wherein the bridge frame includes a front rail, a rear rail, a first side rail extending between the front and rear rails, and a second side rail extending between the front and rear rails, the front rail supporting the upper and lower forward segments, the rear rail supporting the upper and lower rearward segments.

10. The thermal bridge of claim 9, further comprising a front spring element between the upper and lower forward segments proximate to the front rail and a rear spring element between the upper and lower rearward segments proximate to the rear rail.

11. The thermal bridge of claim 1, wherein the spring element is positioned at the upper seam and the lower seam, the spring element including forward spring members engaging the upper forward segments and the lower forward segments to bias the upper forward segments and the lower forward segments away from each other with the opening force, the spring element including rearward spring members engaging the upper rearward segments and the lower rearward segments to bias the upper rearward segments and the lower rearward segments away from each other with the opening force.

12. The thermal bridge of claim 1, wherein the upper spar and the lower spar contain vertical movement of the upper plates and the lower plates in a predetermined confined space.

13. The thermal bridge of claim 1, wherein the upper bridge assembly includes an upper thermal interface configured to be thermally coupled to a heat transfer device, the upper plates and the lower plates being movable relative to each other, relative to the electrical component, and relative to the heat transfer device.

14. The thermal bridge of claim 1, wherein some of the upper plates include upper overlapping regions and some of the lower plates include lower overlapping regions, the upper bridge assembly and the lower bridge assembly being internested such that the upper overlapping regions thermally interface with the lower overlapping regions to thermally couple the upper plates and the lower plates.

15. The thermal bridge of claim 1, wherein the upper plates include upper bridge plates and upper spacer plates between the upper bridge plates, the lower plates including lower bridge plates and lower spacer plates between the lower bridge plates, the upper bridge plates being aligned with the lower spacer plates and the lower bridge plates being aligned with the upper spacer plates.

16. The thermal bridge of claim 15, wherein:
each upper bridge plate includes a base and upper overlapping regions extending from the base at the inner end and wherein each upper spacer plate including a spacer base and pockets formed in the spacer base at the inner end;
each lower bridge plate includes a base and lower overlapping regions extending from the base at the inner end and wherein each lower spacer plate including a spacer base and pockets formed in the spacer base at the inner end;
the upper overlapping regions of the upper bridge plates being aligned with and configured to be received in the pockets of the associated lower spacer plates;
the lower overlapping regions of the lower bridge plates being aligned with and configured to be received in the pockets of the associated upper spacer plates; and
the upper bridge assembly and the lower bridge assembly being internested such that the upper overlapping regions thermally interface with the lower overlapping regions to thermally couple the upper plates and the lower plates.

17. A thermal bridge comprising:
an upper bridge assembly including a plurality of upper plates arranged in an upper plate stack, each upper plate being segmented including an upper forward segment at a front end of the upper plate and an upper rearward segment at a rear end of the upper plate, each upper plate having an upper seam between the upper forward segment and the upper rearward segment, each upper plate having sides between the front end and the rear end, each upper plate having an inner end and an outer end;
a lower bridge assembly including a plurality of lower plates arranged in a lower plate stack, each lower plate being segmented including a lower forward segment at a front end of the lower plate and a lower rearward segment at a rear end of the lower plate, each lower plate having a lower seam between the lower forward segment and the lower rearward segment, each lower plate having sides between the front end and the rear end, each lower plate having an inner end and an outer end, the outer ends of the lower plates configured to face and thermally couple to an electrical component, the sides of some of the lower plates facing the sides of some of the upper plates to thermally interface the lower plates with the upper plates;
a spring element positioned between the upper bridge assembly and the lower bridge assembly at the upper seam and the lower seam, the spring element including forward spring members engaging the upper forward segments and the lower forward segments to bias the upper forward segments and the lower forward segments away from each other with an opening force, the spring element including rearward spring members engaging the upper rearward segments and the lower rearward segments to bias the upper rearward segments and the lower rearward segments away from each other with an opening force; and
a bridge frame supporting the upper plates in the upper plate stack and supporting the lower plates in the lower plate stack to limit spreading apart of the upper and lower plates from each other against the opening forces of the spring element.

18. The thermal bridge of claim 17, wherein the bridge frame includes an upper open limit spar engaging the upper plates at the upper seam to limit spreading apart of the upper plates from the lower plates against the opening forces of the spring element, the bridge frame including a lower open limit spar engaging the lower plates at the lower seam to limit spreading apart of the lower plates from the upper plates against the opening forces of the spring element.

19. The thermal bridge of claim 18, wherein the upper forward segment and the upper rearward segment include upper slots open to the upper seam receiving the upper open limit spar, the lower forward segment and the lower rearward segment include lower slots open to the lower seam receiving the lower open limit spar.

20. The thermal bridge of claim 18, wherein the bridge frame includes a front rail, a rear rail, a first side rail extending between the front and rear rails, a second side rail extending between the front and rear rails, an upper open limit spar between the first and second side rails, and a lower open limit spar between the first and second side rails, the front rail supporting the upper and lower forward segments, the rear rail supporting the upper and lower rearward segments, the upper open limit spar engaging the upper plates at the upper seam to limit spreading apart of the upper plates from the lower plates against the opening forces of the spring element, the lower open limit spar engaging the lower plates at the lower seam to limit spreading apart of the lower plates from the upper plates against the opening forces of the spring element.

21. A thermal bridge comprising:
an upper bridge assembly including a plurality of upper plates arranged in an upper plate stack, each upper plate being segmented including an upper forward segment at a front end of the upper plate and an upper rearward segment at a rear end of the upper plate, each upper plate having an upper seam between the upper forward segment and the upper rearward segment, each upper plate having sides between the front end and the rear end, each upper plate having an inner end and an outer end;
a lower bridge assembly including a plurality of lower plates arranged in a lower plate stack, each lower plate being segmented including a lower forward segment at a front end of the lower plate and a lower rearward segment at a rear end of the lower plate, each lower plate having a lower seam between the lower forward segment and the lower rearward segment, each lower plate having sides between the front end and the rear end, each lower plate having an inner end and an outer end, the outer ends of the lower plates configured to face and thermally couple to an electrical component, the sides of some of the lower plates facing the sides of some of the upper plates to thermally interface the lower plates with the upper plates;
a spring element positioned between the upper bridge assembly and the lower bridge assembly at the upper seam and the lower seam, the spring element including an upper spring member engaging the upper plates to bias the upper plates with an opening force generally away from the lower plates, the spring element including a lower spring member engaging the lower plates to bias the lower plates with an opening force generally away from the upper plates; and
a bridge frame supporting the upper plates in the upper plate stack and supporting the lower plates in the lower plate stack, the bridge frame including an upper open limit spar aligned with the spring element at the upper seam, the upper open limit spar engaging the upper plates at the upper seam to limit spreading apart of the upper plates from the lower plates against the opening forces of the spring element, the bridge frame including a lower open limit spar aligned with the spring element at the upper seam and the lower seam, the lower open limit spar engaging the lower plates at the lower seam to limit spreading apart of the lower plates from the upper plates against the opening forces of the spring element.
